(19) United States
(12) Patent Application Publication
(10) Pub. No.: US 2025/0066910 A1
(43) Pub. Date: Feb. 27, 2025

(54) SYSTEM AND METHOD FOR RECLAIMING TUNGSTEN COMPOUNDS

(71) Applicant: Micron Technology, Inc., Boise, ID (US)

(72) Inventors: John Hopkins, Meridian, ID (US); Jordan D. Greenlee, Boise, ID (US)

(21) Appl. No.: 18/773,920

(22) Filed: Jul. 16, 2024

Related U.S. Application Data
(60) Provisional application No. 63/534,427, filed on Aug. 24, 2023.

(51) Int. Cl. H01J 37/32; C23C 16/44

(52) U.S. Cl. CPC C23C 16/4412

(57) ABSTRACT

A semiconductor manufacture reclamation system and associated methods are shows. Example systems and methods include semiconductor processing machinery and a reaction chamber coupled along a path of a waste gas vent. Systems and methods are shown that include an amount of silicon to react with a waste gas including tungsten.

### PRIORITY APPLICATION

This application claims the benefit of priority to U.S. Provisional Application Ser. No. 63/534,427, filed Aug. 24, 2023, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to systems that utilize computer systems such as those described above, to control a heat transfer system in a manufacturing environment.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates a semiconductor manufacture reclamation system in accordance with some example embodiments.

FIG. 3 illustrates an example method flow diagram in accordance with other example embodiments.

FIG. 4 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

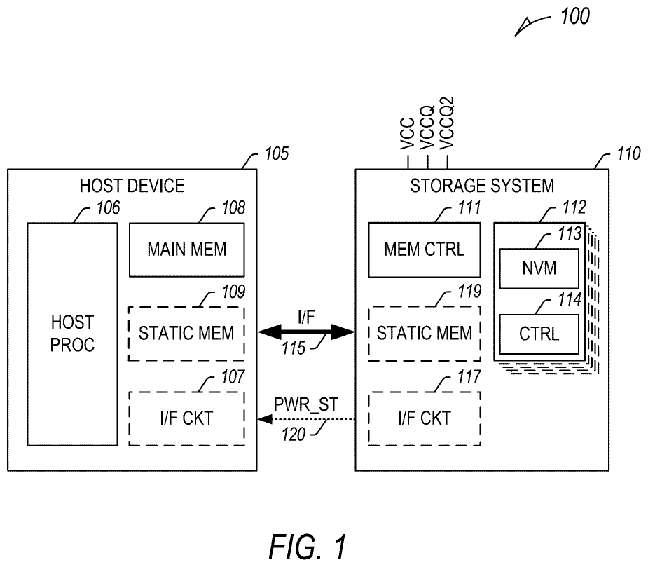

FIG. 1 illustrates an example system (e.g., a host system) 100 including a host device 105 and a storage system 110 configured to communicate over a communication interface (I/F) 115 (e.g., a bidirectional parallel or serial communication interface). In an example, the communication interface 115 can be referred to as a host interface. The host device 105 can include a host processor 106 (e.g., a host central processing unit (CPU) or other processor or processing circuitry, such as a memory management unit (MMU), interface circuitry, etc.). In certain examples, the host device 105 can include a main memory (MAIN MEM) 108 (e.g., DRAM, etc.) and optionally, a static memory (STATIC MEM) 109, to support operation of the host processor (HOST PROC) 106.

The storage system 110 can include a non-volatile memory device. For example, the communication interface 115 of a UFS device can include a serial or parallel bidirectional interface, such as defined in one or more Joint Electron Device Engineering Council (JEDEC) standards.

The storage system 110 can include a memory controller (MEM CTRL) 111 and a non-volatile memory device 112. The memory controller 111 can optionally include a limited amount of static memory 119 to support operations of the memory controller 111. In an example, the non-volatile memory device 112 can include a number of non-volatile memory devices (e.g., dies or LUNs), such as one or more stacked flash memory devices (e.g., as illustrated with the stacked dashes underneath the non-volatile memory device 112), etc., each including non-volatile memory (NVM) 113 (e.g., one or more groups of non-volatile memory cells) and a device controller (CTRL) 114 or other periphery circuitry thereon (e.g., device logic, etc.), and controlled by the memory controller 111 over an internal storage-system communication interface (e.g., an Open NAND Flash Interface (ONFI) bus, etc.) separate from the communication interface 115. Control circuitry, as used herein, can refer to one or more of the memory controller 111, the device controller 114, or other periphery circuitry in the storage system 110, the NVM device 112, etc.

Flash memory devices typically include one or more groups of one-transistor, floating gate (FG) or replacement gate (RG) (or charge trapping) storage structures (memory cells). The memory cells of the memory array are typically arranged in a matrix. The gates of each memory cell in a row of the array are coupled to an access line (e.g., a word line). In NOR architecture, the drains of each memory cell in a column of the array are coupled to a data line (e.g., a bit line). In NAND architecture, the drains of each memory cell in a column of the array are coupled together in series, source to drain, between a source line and a bit line.

Each memory cell in a NOR, NAND, 3D XPoint, FeRAM, MRAM, or one or more other architecture semiconductor memory array can be programmed individually or collectively to one or a number of programmed states. A single-level cell (SLC) can represent one bit of data per cell in one of two programmed states (e.g., 1 or 0). A multi-level cell (MLC) can represent two or more bits of data per cell in a number of programmed states (e.g., 2ⁿ, where n is the number of bits of data). In certain examples, MLC can refer to a memory cell that can store two bits of data in one of 4 programmed states. A triple-level cell (TLC) can represent three bits of data per cell in one of 8 programmed states. A quad-level cell (QLC) can represent four bits of data per cell in one of 16 programmed states. In other examples, MLC can refer to any memory cell that can store more than one bit of data per cell, including TLC and QLC, etc.

In three-dimensional (3D) architecture semiconductor memory device technology, memory cells can be stacked, increasing the number of tiers, physical pages, and accordingly, the density of memory cells in a memory device. Data is often stored arbitrarily on the storage system as small units. Even if accessed as a single unit, data can be received in small, random 4-16 k single file reads (e.g., 60%-80% of operations are smaller than 16 k). It is difficult for a user and even kernel applications to indicate that data should be stored as one sequential cohesive unit. File systems are typically designed to optimize space usage, and not sequential retrieval space.

The memory controller 111 can receive instructions from the host device 105, and can communicate with the non-volatile memory device 112, such as to transfer data to (e.g., write or erase) or from (e.g., read) one or more of the memory cells of the non-volatile memory device 112. The memory controller 111 can include, among other things, circuitry or firmware, such as a number of components or integrated circuits. For example, the memory controller 111 can include one or more memory control units, circuits, or components configured to control access across the memory array and to provide a translation layer between the host device 105 and the storage system 100, such as a memory manager, one or more memory management tables, etc.

The memory manager can include, among other things, circuitry or firmware, such as a number of components or integrated circuits associated with various memory management functions, including, among other functions, wear leveling (e.g., garbage collection or reclamation), error detection or correction, block retirement, or one or more other memory management functions. The memory manager 125 can parse or format host commands (e.g., commands received from the host device 105) into device commands (e.g., commands associated with operation of a memory array, etc.), or generate device commands (e.g., to accomplish various memory management functions) for the device controller 114 or one or more other components of the storage system 110.

The memory manager can include a set of management tables configured to maintain various information associated with one or more component of the storage system 110 (e.g., various information associated with a memory array or one or more memory cells coupled to the memory controller 111). For example, the management tables can include information regarding block age, block erase count, error history, or one or more error counts (e.g., a write operation error count, a read bit error count, a read operation error count, an erase error count, etc.) for one or more blocks of memory cells coupled to the memory controller 111. In certain examples, if the number of detected errors for one or more of the error counts is above a threshold, the bit error can be referred to as an uncorrectable bit error. The management tables can maintain a count of correctable or uncorrectable bit errors, among other things. In an example, the management tables can include translation tables or a L2P mapping.

The memory manager can implement and use data structures to reduce storage system 110 latency in operations that involve searching L2P tables for valid pages, such as garbage collection. To this end, the memory manager is arranged to maintain a data structure (e.g., table region data structure, tracking data structure, etc.) for a physical block. The data structure includes indications of L2P mapping table regions, of the L2P table. In certain examples, the data structure is a bitmap (e.g., a binary array). In an example, the bitmap includes a bit for each region of multiple, mutually exclusive, regions that span the L2P table.

The non-volatile memory device 112 or the non-volatile memory 113 (e.g., one or more 3D NAND architecture semiconductor memory arrays) can include a number of memory cells arranged in, for example, a number of devices, planes, blocks, physical pages, super blocks, or super pages. As one example, a TLC memory device can include 18,592 bytes (B) of data per page, 1536 pages per block, 548 blocks per plane, and 4 planes per device. As another example, an MLC memory device can include 18,592 bytes (B) of data per page, 1024 pages per block, 548 blocks per plane, and 4 planes per device, but with half the required write time and twice the program/erase (P/E) cycles as a corresponding TLC memory device. Other examples can include other numbers or arrangements. A super block can include a combination of multiple blocks, such as from different planes, etc., and a window can refer to a stripe of a super block, typically matching a portion covered by a physical-to-logical (P2L) table chunk, etc., and a super page can include a combination of multiple pages.

The term “super” can refer to a combination or multiples of a thing or things. For examples, a super block can include a combination of blocks. If a memory device includes 4 planes, a super block may refer to the same block on each plane, or a pattern of blocks across the panes (e.g., a combination of block 0 on plane 0, block 1 on plane 1, block 2 on plane 2, and block 3 on plane 3, etc.). In an example, if a storage system includes multiple memory devices, the combination or pattern of blocks can extend across the multiple memory devices. The term “stripe” can refer to a pattern of combination or pattern of a piece or pieces of a thing or things. For example, a stripe of a super block can refer to a combination or pattern of pages from each block in the super block.

In operation, data is typically written to or read from the storage system 110 in pages and erased in blocks. However, one or more memory operations (e.g., read, write, erase, etc.) can be performed on larger or smaller groups of memory cells, as desired. For example, a partial update of tagged data from an offload unit can be collected during data migration or garbage collection to ensure it was re-written efficiently. The data transfer size of a memory device is typically referred to as a page, whereas the data transfer size of a host device is typically referred to as a sector. Although a page of data can include a number of bytes of user data (e.g., a data payload including a number of sectors of data) and its corresponding metadata, the size of the page often refers only to the number of bytes used to store the user data. As an example, a page of data having a page size of 4 kB may include 4 kB of user data (e.g., 8 sectors assuming a sector size of 512B) as well as a number of bytes (e.g., 32B, 54B, 224B, etc.) of auxiliary or metadata corresponding to the user data, such as integrity data (e.g., error detecting or correcting code data), address data (e.g., logical address data, etc.), or other metadata associated with the user data.

Different types of memory cells or memory arrays can provide for different page sizes, or may require different amounts of metadata associated therewith. For example, different memory device types may have different bit error rates, which can lead to different amounts of metadata necessary to ensure integrity of the page of data (e.g., a memory device with a higher bit error rate may require more bytes of error correction code (ECC) data than a memory device with a lower bit error rate). As an example, an MLC NAND flash device may have a higher bit error rate than a corresponding SLC NAND flash device. As such, the MLC device may require more metadata bytes for error data than the corresponding SLC device.

In an example, the data in a chunk or data unit can be handled in an optimized manner throughout its tenure on the storage system. For example, the data is managed as one unit during data migration (e.g., garbage collection, etc.) such that the efficient read/write properties are preserved as data is moved to its new physical location on the storage system. In certain examples, the only limit to the number of chunks, data units, or blocks configurable for storage, tagging, etc., are the capacities of the system.

One or more of the host device 105 or the storage system 110 can include interface circuitry, such as host interface circuitry (I/F CKT) 107 or storage interface circuitry (I/F CKT) 117, configured to enable communication between components of the host system 100. Each interface circuitry can include one or more UFS Interconnect (UIC) layers, such as mobile industry processor interface (MIPI) Unified Protocol (UniPro) and M-PHY layers (e.g., physical layers), including circuit components and interfaces. The M-PHY layer includes the differential transmit (TX) and receive (RX) signaling pairs (e.g., DIN_t, DIN_c and DOUT_t, DOUT_c, etc.). In certain examples, the host I/F CKT 107 can include a controller (e.g., a UFS controller), a driver circuit (e.g., a UFS driver), etc. Although described herein with respect to the UniPro and M-PHY layers, one or more other set of circuit components or interfaces can be used to transfer data between circuit components of the host system 100.

Components of the host system 100 can be configured to receive or operate using one or more host voltages, including, for example, VCC, VCCQ, and, optionally, VCCQ2. In certain examples, one or more of the host voltages, or power rails, can be managed or controlled by a power management integrated circuit (PMIC) 121. In certain examples, VCC can be a first supply voltage (e.g., 2.7V-3.3V, 1.7V-1.95V, etc.). In an example, one or more of the static memory 119 or the non-volatile memory devices 112 can require VCC for operation. VCCQ can be a second supply voltage, lower than the VCC (e.g., 1.1V-1.3V, etc.). In an example, one or more of the memory controller 111, the communication interface 115, or memory I/O or other low voltage blocks can optionally require VCCQ for operation. VCCQ2 can be a third supply voltage between VCC and VCCQ (e.g., 1.7V-1.95V, etc.). In an example, one or more of the memory controller 111 of the communication interface, or other low voltage block can optionally require VCCQ2. Each host voltage can be set to provide voltage at one or more current levels, in certain examples, controllable by one or more device descriptors and levels (e.g., between [0:15], each representing a different maximum expected source current, etc.).

One or more semiconductor dies, such as silicon dies, are included in the host system 100. Examples of semiconductor dies include, but are not limited to, memory dies, processor dies, graphics dies, etc. Manufacture of one or more of the semiconductor dies in the host system 100 includes a number of units of semiconductor processing machinery. Silicon ingots are formed, and sliced into silicon wafers. The wafers are then processed through a series of stages into silicon dies with integrated circuits (ICs) formed on and within the dies. One useful operation in manufacture of semiconductor dies is tungsten deposition. Tungsten metal is used in a number of components in semiconductor device construction. Examples include, but are not limited to, diffusion barrier layers, adhesion layers, conductive plugs between layers, etc. In one example, a gas containing a gaseous tungsten compound is introduced to a surface of a silicon wafer and is reacted to deposit tungsten metal, or a solid tungsten compound. One example of a gaseous tungsten compound includes tungsten hexafluoride (WF6). When processing semiconductor dies such as silicon dies, it is desired to reduce waste byproducts of manufacturing, such as unused tungsten hexafluoride.

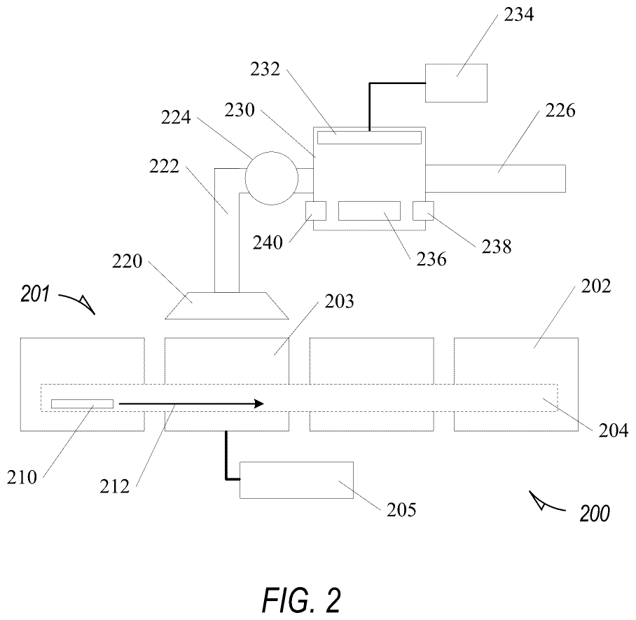

FIG. 2 shows a semiconductor manufacture system 200 that includes equipment for reclamation of tungsten from unused tungsten hexafluoride. The reclamation equipment reduces waste tungsten hexafluoride, and also produces solid tungsten containing compounds that can be sold for reuse, or recycled for other uses in manufacturing.

The semiconductor manufacture system 200 includes a processing processing line 201, including a number of units of semiconductor processing machinery 202. A conveyor system 204 is shown. When in operation, the conveyor system 204 is configured to move a semiconductor wafer 210 from one unit of semiconductor processing machinery 202 to the next, as shown by arrow 212. In one example, the conveyor system 204 maintains a vacuum between stations of different units of semiconductor processing machinery 202. Many semiconductor processing operations require a vacuum to perform various processing operations. In FIG. 2, a chemical vapor deposition system 203 is shown as one of the units of semiconductor processing machinery 202. In one example, the chemical vapor deposition system 203 includes a tungsten hexafluoride deposition system. Although tungsten hexafluoride is used as an example, other gasses that include tungsten are within the scope of the invention. Other tungsten containing gasses include, but are not limited to tungsten chloride (WCl₆) and tungsten bromide (WBr₆).

In the example of FIG. 2, a supply of tungsten hexafluoride 205 is shown coupled to the chemical vapor deposition system 203. In operation, when the semiconductor wafer 210 is at the chemical vapor deposition system 203 along the conveyor system 204, tungsten hexafluoride is introduced to a surface of the semiconductor wafer 210. A chemical reaction is induced, and tungsten metal is deposited in select regions of the semiconductor wafer 210, for example, by masking, or selective chemisorption. In one example, an amount of unused tungsten hexafluoride remains and is included in a waste gas, along with any catalyst or reaction chemicals involved in the deposition process.

A waste gas vent 220 is shown coupled to the chemical vapor deposition system 203. A waste gas conduit 222 is shown leading from the waste gas vent 220 to a reaction chamber 230. Although the waste gas vent 220 is shown adjacent to the chemical vapor deposition system 203, the invention is not so limited. In one example, the waste gas conduit 222 is directly coupled to the chemical vapor deposition system 203 without a waste gas vent 220 to better facilitate maintaining a vacuum within the chemical vapor deposition system 203.

In one example, a fan 224 or other pressurization system promotes movement of waste gas including tungsten from the chemical vapor deposition system 203 to the reaction chamber 230. In one example, the reaction chamber is adapted to include an amount of silicon during operation. In one example, a receptacle 236 is included within the reaction chamber 230 to hold the amount of silicon. In one example, a supply system 240 is included to add silicon to the reaction chamber 230 as needed. In one example, the receptacle 236 further collects a solid reaction byproduct such as metallic tungsten as described in examples below.

Under selected reaction chamber condition, the amount of silicon reacts with waste gas that includes tungsten to produce a solid material that includes tungsten. One useful reaction includes:

$$2 {WF}_{6} + 3 Si \to 2 W + 3 {SiF}_{4}$$

In one example, the amount of silicon reacts with tungsten hexafluoride to produce byproducts of tungsten metal and silicon tetrafluoride gas. In the tungsten metal/silicon tetrafluoride example, the reaction is best facilitated at elevated temperature. A heater 232 is included within the reaction chamber 230 to provide improved reaction conditions. A controller 234 is included, and coupled to the heater. Feedback circuitry (not shown) provides temperature control within the reaction chamber 230 to better facilitate the reaction. In one example, the controller 234 includes settings to control a temperature within the reaction chamber between 300 degrees C. and 500 degrees C. In one example, the controller 234 includes settings to control a temperature within the reaction chamber between 350 degrees C. and 450 degrees C. In one example, the controller 234 includes settings to control a temperature within the reaction chamber of approximately 400 degrees C.

By reacting waste tungsten hexafluoride with silicon to produce a solid containing tungsten, an amount of waste gas is reduced, and waste gas abatement systems can be designed with lower capacity, or eliminated. Additionally, using the reaction above, solid metallic tungsten is a byproduct. The solid metallic tungsten can be sold as a commodity, or recycled for use as a component of a tooling material, or in other manufacturing processes.

In one example, the silicon used for the reaction in the reaction chamber 230 comes from other waste processes in wafer manufacturing. One example source of waste silicon includes wafers that are used to qualify manufacturing equipment before production begins. Manufacturing equipment often requires a number of blank or test samples to be run to ensure that the equipment is operating within specifications. In one example waste wafers from qualification are used in the reaction chamber 230 to reclaim tungsten as described above. This method further reduces overall waste in semiconductor manufacturing by consuming waste silicon to accomplish the reduction in tungsten gas waste.

FIG. 2 further shows a collection and removal port 238 coupled to the reaction chamber 230 for collection and removal of a tungsten based solid material. An exhaust vent 226 is further included and attached to the reaction chamber 230. In one example, the exhaust vent 226 is configured to transfer a waste gas of the reaction within reaction chamber 230 after reclamation of tungsten. In the example described above, silicon tetrafluoride is vented from the exhaust vent 226 after reclaiming tungsten.

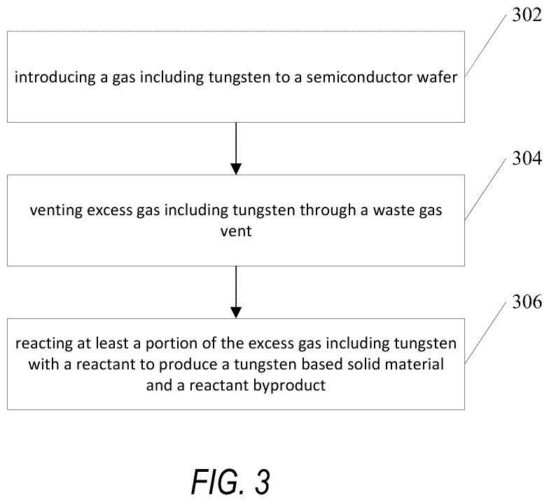

FIG. 3 shows a flow diagram of one example method of reclamation in semiconductor manufacturing. In operation 302 a gas including tungsten is introduced to a semiconductor wafer. In operation 304, excess gas including tungsten is vented through a waste gas vent. In operation 306, at least a portion of the excess gas including tungsten is reacted with a reactant to produce a tungsten based solid material and a reactant byproduct.

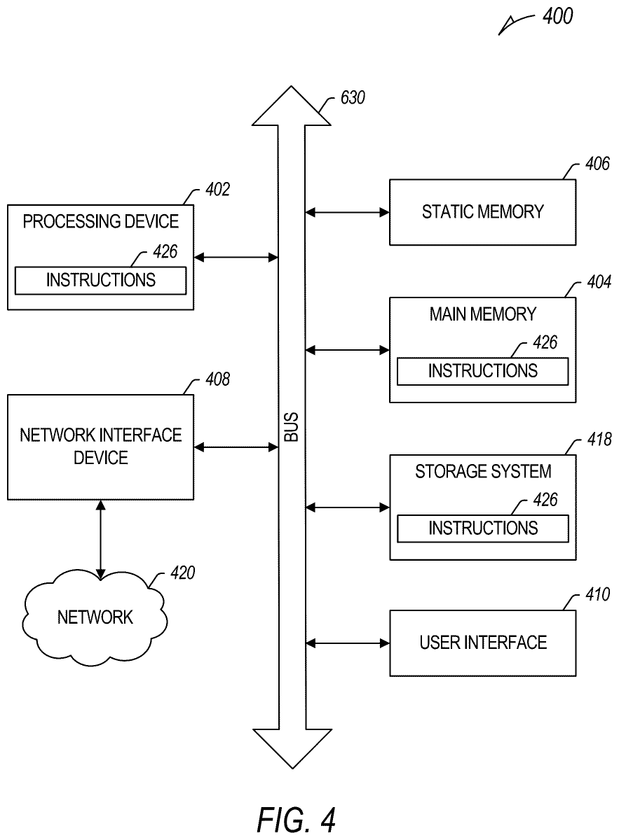

FIG. 4 illustrates a block diagram of an example machine (e.g., a host system) 400 that includes one or more silicon dies that are manufactured using devices and methods described in examples above. Example machines as described in FIG. 4 may also be used to facilitate control of systems that implement methods as described in examples above. In alternative embodiments, the machine 400 may operate as a standalone device or may be connected (e.g., networked) to other machines. In a networked deployment, the machine 400 may operate in the capacity of a server machine, a client machine, or both in server-client network environments. In an example, the machine 400 may act as a peer machine in peer-to-peer (P2P) (or other distributed) network environment. The machine 400 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 400 may include a processing device 402 (e.g., a hardware processor, a central processing unit (CPU), a graphics processing unit (GPU), a hardware processor core, or any combination thereof, etc.), a main memory 404 (e.g., read-only memory (ROM), dynamic random-access memory (DRAM) such as synchronous DRAM (SDRAM) or Rambus DRAM (RDRAM), etc.), a static memory 406 (e.g., static random-access memory (SRAM), etc.), and a storage system 418, some or all of which may communicate with each other via a communication interface (e.g., a bus) 430.

The processing device 402 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 402 can also be one or more special-purpose processing devices such as an application specific integrated circuit (ASIC), a field programmable gate array (FPGA), a digital signal processor (DSP), network processor, or the like. The processing device 402 can be configured to execute instructions 426 for performing the operations and steps discussed herein. The computer system 400 can further include a network interface device 408 to communicate over a network 420.

The storage system 418 can include a machine-readable storage medium (also known as a computer-readable medium) on which is stored one or more sets of instructions 426 or software embodying any one or more of the methodologies or functions described herein. The instructions 426 can also reside, completely or at least partially, within the main memory 404 or within the processing device 402 during execution thereof by the computer system 400, the main memory 404 and the processing device 402 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 400 may further include a user interface 410, such as one or more of a display unit, an alphanumeric input device (e.g., a keyboard), and a user interface (UI) navigation device (e.g., a mouse), etc. In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 400 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 426 (e.g., software, programs, an operating system (OS), etc.) or other data are stored on the storage system 418 can be accessed by the main memory 404 for use by the processing device 402. The main memory 404 (e.g., DRAM) is typically fast, but volatile, and thus a different type of storage than the storage system 418 (e.g., an SSD), which is suitable for long-term storage, including while in an “off” condition. The instructions 426 or data in use by a user or the machine 400 are typically loaded in the main memory 404 for use by the processing device 402. When the main memory 404 is full, virtual space from the storage system 418 can be allocated to supplement the main memory 404; however, because the storage system 418 device is typically slower than the main memory 404, and write speeds are typically at least twice as slow as read speeds, use of virtual memory can greatly reduce user experience due to storage system latency (in contrast to the main memory 404, e.g., DRAM). Further, use of the storage system 418 for virtual memory can greatly reduce the usable lifespan of the storage system 418.

The instructions 424 may further be transmitted or received over a network 420 using a transmission medium via the network interface device 408 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 408 may include one or more physical jacks (e.g., Ethernet, coaxial, or phone jacks) or one or more antennas to connect to the network 420. In an example, the network interface device 408 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 400, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Example 1 includes a semiconductor manufacture reclamation system. The semiconductor manufacture reclamation system includes a unit of semiconductor processing machinery, a waste gas vent coupled to the unit of semiconductor processing machinery, and a reaction chamber coupled along a path of the waste gas vent, wherein the reaction chamber includes an amount of silicon to react with a waste gas including tungsten.

Example 2 includes the semiconductor manufacture reclamation system of Example 1, wherein the unit of semiconductor processing machinery includes a chemical vapor deposition system.

Example 3 includes the semiconductor manufacture reclamation system of any one of Examples 1-2, wherein the chemical vapor deposition system includes a tungsten hexafluoride deposition system.

Example 4 includes the semiconductor manufacture reclamation system of any one of Examples 1-3, wherein the reaction chamber includes a heater.

Example 5 includes the semiconductor manufacture reclamation system of any one of Examples 1-4, wherein the reaction chamber includes a controller to maintain a temperature greater than 300 degrees C.

Example 6 includes the semiconductor manufacture reclamation system of any one of Examples 1-5, wherein the reaction chamber includes a controller to maintain a temperature between 300 degrees C. and 500 degrees C.

Example 7 includes the semiconductor manufacture reclamation system of any one of Examples 1-6, wherein the reaction chamber includes an amount of waste silicon from a semiconductor die processing system.

Example 8 includes the semiconductor manufacture reclamation system of any one of Examples 1-7, further including a collection and removal system coupled to the reaction chamber for collection and removal of a tungsten based solid material.

Example 9 includes the semiconductor manufacture reclamation system of any one of Examples 1-8, further including a reactant supply system coupled to the reaction chamber for adding silicon.

Example 10 includes a method of reclamation in semiconductor manufacturing. The method includes introducing a gas including tungsten to a semiconductor wafer, venting excess gas including tungsten through a waste gas vent, and reacting at least a portion of the excess gas including tungsten with a reactant to produce a tungsten based solid material and a reactant byproduct.

Example 11 includes the method of Example 10, wherein introducing a gas including tungsten includes introducing a gas including tungsten hexafluoride.

Example 12 includes the method of any one of Examples 10-11, wherein venting excess gas includes venting a gas including tungsten hexafluoride.

Example 13 includes the method of any one of Examples 10-12, wherein reacting at least a portion of the excess gas including tungsten with a reactant includes reacting with silicon.

Example 14 includes the method of any one of Examples 10-13, wherein reacting with silicon includes reacting with waste silicon from a semiconductor die processing system.

Example 15 includes the method of any one of Examples 10-14, wherein reacting with silicon includes reacting to produce tungsten metal and silicon tetrafluoride.

Example 16 includes the method of any one of Examples 10-15, further including replenishing silicon as it is consumed.

Example 17 includes the method of any one of Examples 10-16, further including removing tungsten metal periodically as it is produced.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor manufacture reclamation system, comprising:
a unit of semiconductor processing machinery;
a waste gas vent coupled to the unit of semiconductor processing machinery; and
a reaction chamber coupled along a path of the waste gas vent, wherein the reaction chamber includes an amount of silicon to react with a waste gas including tungsten.

2. The semiconductor manufacture reclamation system of claim 1, wherein the unit of semiconductor processing machinery includes a chemical vapor deposition system.

3. The semiconductor manufacture reclamation system of claim 2, wherein the chemical vapor deposition system includes a tungsten hexafluoride deposition system.

4. The semiconductor manufacture reclamation system of claim 1, wherein the reaction chamber includes a heater.

5. The semiconductor manufacture reclamation system of claim 4, wherein the reaction chamber includes a controller to maintain a temperature greater than 300 degrees C.

6. The semiconductor manufacture reclamation system of claim 4, wherein the reaction chamber includes a controller to maintain a temperature between 300 degrees C. and 500 degrees C.

7. The semiconductor manufacture reclamation system of claim 1, wherein the reaction chamber includes an amount of waste silicon from a semiconductor die processing system.

8. The semiconductor manufacture reclamation system of claim 1, further including a collection and removal system coupled to the reaction chamber for collection and removal of a tungsten based solid material.

9. The semiconductor manufacture reclamation system of claim 8, further including a reactant supply system coupled to the reaction chamber for adding silicon.

10. A method of reclamation in semiconductor manufacturing, comprising:
introducing a gas including tungsten to a semiconductor wafer;
venting excess gas including tungsten through a waste gas vent; and
reacting at least a portion of the excess gas including tungsten with a reactant to produce a tungsten based solid material and a reactant byproduct.

11. The method of claim 10, wherein introducing a gas including tungsten includes introducing a gas including tungsten hexafluoride.

12. The method of claim 10, wherein venting excess gas includes venting a gas including tungsten hexafluoride.

13. The method of claim 10, wherein reacting at least a portion of the excess gas including tungsten with a reactant includes reacting with silicon.

14. The method of claim 13, wherein reacting with silicon includes reacting with waste silicon from a semiconductor die processing system.

15. The method of claim 13, wherein reacting with silicon includes reacting to produce tungsten metal and silicon tetrafluoride.

16. The method of claim 15, further including replenishing silicon as it is consumed.

17. The method of claim 16, further including removing tungsten metal periodically as it is produced.
